(19) United States
(12) Patent Application Publication
(10) Pub. No.: US 2007/0166901 A1
(43) Pub. Date: Jul. 19, 2007

(54) METHOD FOR FABRICATING SOI DEVICE

(76) Inventor: Jin-Yuan Lee, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/689,520

(22) Filed: Mar. 22, 2007

Related U.S. Application Data
(62) Division of application No. 11/162,087, filed on Aug. 29, 2005.

(51) Int. Cl. H01L 21/84; H01L 21/30; H01L 21/20

(52) U.S. Cl. 438/164; 438/481; 438/479; 438/459; 438/152

(57) ABSTRACT

A semiconductor-on-insulator (SOI) device is described, including a substrate, a first insulating layer and a second insulating layer on the substrate, a semiconductor layer covering the first and the second insulating layers, a gate dielectric layer and a gate on the semiconductor layer, and two doped regions as source/drain regions in the semiconductor layer beside the gate. The second insulating layer has a pattern, and has a material different from that of the first insulating layer.

### CROSS-REFERENCE TO RELATED APPLICATION

This application is a divisional of a prior application Ser. No. 11/162,087, filed Aug. 29, 2005. The entirety of the above-mentioned patent application is hereby incorporated by reference herein and made a part of this specification.

### BACKGROUND OF THE INVENTION

1. Field of the Invention

The present invention relates to a semiconductor device and a semiconductor process. More particularly, the present invention relates to a semiconductor-on-insulator (SOI) device, and a method for fabricating the same.

2. Description of the Related Art

Recently, SOI devices, especially silicon-on-insulator MOS devices, are widely used for their excellent electrical properties including lower threshold voltage, smaller parasitic capacitance, less current leakage and good switching property, etc. The good switching property or less current leakage in the channel layer is due to the thinness of the channel layer as a part of the thin semiconductor layer of the SOI substrate. When the thickness of the channel layer of an SOI device is reduced such that the depletion region therein extends to the insulator during operation, the SOI device is a fully depleted (FD) device. Otherwise, the SOI device is a partially depleted device.

Since the thickness of the channel layer has substantial impact on the threshold voltage of a fully depleted SOI device, the process for forming the semiconductor on the insulator has to be well designed to precisely control the thickness of the channel layer. A method for this purpose is disclosed in U.S. Pat. No. 6,228,691, in which an epitaxial lateral overgrowth (ELO) method is utilized to fill shallow openings on the insulator to obtain an SOI substrate of uniform thickness.

On the other hand, the thickness of the channel layer and that of the S/D regions cannot be adjusted respectively in a traditional SOI device fabricating process. One method for respectively adjusting the thicknesses is taught in U.S. Pat. No. 5,485,028, in which the portion of the semiconductor layer as the channel layer is etched and thinned to reduce only the thickness of the channel layer. Alternatively, the portions of the insulator under the S/D regions are etched and thinned previously to increase the thickness of the corresponding portions of the semiconductor layer which is then doped as S/D regions.

Moreover, U.S. Pat. No. 6,656,810 discloses a method of reducing the thickness of the channel layer by conducting LOCOS (local oxidation of silicon) to thin down a portion of the silicon layer and form a channel layer. U.S. Pat. No. 6,841,831 further teaches a method for forming a thinned channel layer and a gate that is self-aligned with the thinned channel layer. In the method, a dummy gate is formed and then removed to form an opening, and the semiconductor layer exposed in the opening is etched and thinned to form a channel layer. After a gate dielectric layer is formed on the channel layer, the gate is formed in the opening self-aligned with the channel layer.

However, since the etching depth of the semiconductor layer or the insulator and the degree of LOCOS is not easy to control, the electrical properties of the SOI devices, especially the FD SOI devices, are difficult to keep uniform.

### SUMMARY OF THE INVENTION

In view of the foregoing, this invention provides an SOI device that includes two different insulating layers as the insulator part to control the electrical properties of the SOI device.

This invention also provides a method for fabricating an SOI device, wherein two different insulating layers are formed so that the electrical properties of the SOI device can be easily controlled.

The SOI device of this invention includes a substrate, a first insulating layer on the substrate, a second insulating layer on the first insulating layer, a semiconductor layer covering the first and the second insulating layers, a gate dielectric layer on the semiconductor layer, a gate on the gate dielectric layer, and two doped regions as source and drain (S/D) regions in the semiconductor layer beside the gate. The second insulating layer has a pattern, and a material different from that of the first insulating layer.

In the above SOI device of this invention, when a portion of the second insulating layer is under the channel layer in the semiconductor layer under the gate, the channel layer can have a smaller thickness so that the SOI device is a fully depleted one. On the contrary, when there is no second insulating layer under the channel layer, the channel layer can have a larger thickness so that the SOI device is a partially depleted one. Similarly, when a portion of the second insulating layer is under a doped region, the doped region can have a smaller thickness; when there is no second insulating layer under a doped region, the doped region can have a larger thickness and lower electrical resistance.

Moreover, in some embodiments of the above SOI device, a body contact is further disposed through the first insulating layer (or through both the second and the first insulating layers) to electrically connect a doped region (or the semiconductor layer excluding the two doped regions) to the substrate (or a well or buried layer in the substrate).

The method for fabricating an SOI device of this invention is described as follows. A first insulating layer is formed on a substrate, and then a second insulating layer is formed on the first insulating layer. The second insulating layer is defined, and then a semiconductor layer is formed covering the first and the second insulating layers. At least one semiconductor device is then formed based on the semiconductor layer.

In preferred embodiments of this invention, the semiconductor device includes a MOS transistor that may be made by forming a gate dielectric on the semiconductor layer, forming a gate on the gate dielectric and then forming two doped regions as S/D regions in the semiconductor layer beside the gate. When the portion of the second insulating layer in the area corresponding to the channel layer is not removed while defining the second insulating layer, the SOI device can be formed with a thinner channel layer to be a fully depleted one. When the portion of the second insulating layer in the area corresponding to the channel layer is removed, however, the SOI device can be formed with a thicker channel layer to be a partially depleted one.

Similarly, when the portion of the second insulating layer in the area corresponding to a doped region is not removed, the doped region can have a small thickness. When the portion of the second insulating layer in the area corresponding to a doped region is removed, the doped region can have larger thickness and lower resistance. Accordingly, the thickness of the channel layer and that of the doped region can be adjusted respectively by patterning the second insulating layer in the above method of this invention.

Moreover, in some embodiments of the above method for fabricating an SOI device, the first insulating layer exposed by the patterned second insulating layer is also patterned to form an opening therein. The opening may be formed for fabricating a body contact between the substrate and a doped region or one between the substrate and the semiconductor layer excluding the two doped regions. Alternatively, the opening may be formed merely for exposing a portion of the substrate for a subsequent epitaxial growth process for forming the semiconductor layer, while an isolation structure will be formed through the opening, removing the entire portion of the semiconductor layer in the opening. In certain embodiments, the opening is formed in the first insulating layer for both purposes.

Since the thickness of the second insulating layer can be precisely controlled and the material of the same is different from that of the first insulating layer, the etching of the second insulating layer can be easily controlled in the above method of this invention, so that the thickness of the channel layer and/or the S/D regions of the SOI devices can be precisely controlled to obtain more uniform electrical properties.

It is to be understood that both the foregoing general description and the following detailed description are exemplary, and are intended to provide further explanation of the invention as claimed.

### BRIEF DESCRIPTION OF THE DRAWINGS

FIGS. 1-3 illustrate three examples of fully depleted SOI devices according to a first embodiment of this invention.

FIGS. 4-6 illustrate four examples of partially depleted SOI devices according to a second embodiment of this invention.

FIG. 7 illustrates an example of a semiconductor product that integrates an FD-SOI device and a partially depleted SOI device according to a third embodiment of this invention.

FIGS. 8A-8H illustrate, in a cross-sectional view, a process flow of fabricating an SOI device according to a fourth embodiment of this invention.

FIG. 9 illustrates an epitaxial layer formed by filling a region where only the second insulating layer is etched off to form a cavity completely isolated from the substrate by the first insulating layer according to the fourth embodiment.

### DESCRIPTION OF THE EMBODIMENTS

### First Embodiment

FIGS. 1-3 illustrate three examples of fully depleted SOI devices according to the first embodiment of this invention.

Referring to FIG. 1, the SOI device includes a substrate 100, a first insulating layer 120 on the substrate 100, a second insulating layer 130 on the first insulating layer 120, a channel layer 140 on the second insulating layer 130, a gate dielectric layer 142 on the channel layer 140, a gate 144 on the gate dielectric layer 142, and two doped regions 147 as S/D regions beside the channel layer 140, wherein the channel layer 140 and the two doped regions 147 are defined from the same semiconductor layer 135, which is the semiconductor part of the SOI structure. The materials of the first insulating layer 120 and the second insulating layer 130 are different, wherein the first insulating layer 120 can be a silicon oxide layer and the second insulating layer 130 can be a silicon nitride layer, for example.

The semiconductor layer 135 has a substantially planar surface and a portion of the second insulating layer 130 is under the channel layer 140. The channel layer 140 is sufficiently thin, for example, as thin as 10-60 nm, so as to form a fully depleted SOI device. A doped region 147 may include a heavily doped portion 150 and a lightly doped portion 148, while preferably there is no second insulating layer 130 under the heavily doped portion 150, and the heavily doped portion 150 may have a thickness of up to 60-250 nm to have a low resistance. The heavily doped region and lightly doped region can be formed by using the conventional implantation and spacer fabricating process.

In addition, the active area of the SOI device may be defined by an isolation structure 110, such as a shallow trench isolation (STI) structure. The gate dielectric layer 142 may be a thin silicon oxide layer or a high-k material layer, and the material of the gate 144 may be polysilicon. When the gate 144 includes silicon, a self-aligned metal silicide (salicide) layer 152 may be formed on each of the gate 144 and the heavily doped portions 150 of the two doped regions 147 to reduce their resistance, wherein the spacer 146 prevents the bridging of silicides between the gate 144 and the two doped regions 147. In addition, the material of the salicide layer 152 may be titanium silicide, cobalt silicide or nickel silicide, etc.

Referring to FIG. 2, the example of a fully depleted SOI device is similar to that shown in FIG. 1, except that the gate 144 has a polycide structure including a poly-Si layer 154 and a metal silicide layer 156, such as a tungsten silicide layer or a molybdenum silicide layer. The polycide layer may have a cap layer 158 thereon, such as a SiN layer, to prevent the bridging between the gate 144 and the two doped regions 147 during the fabricating process of salicide on the S/D regions 147.

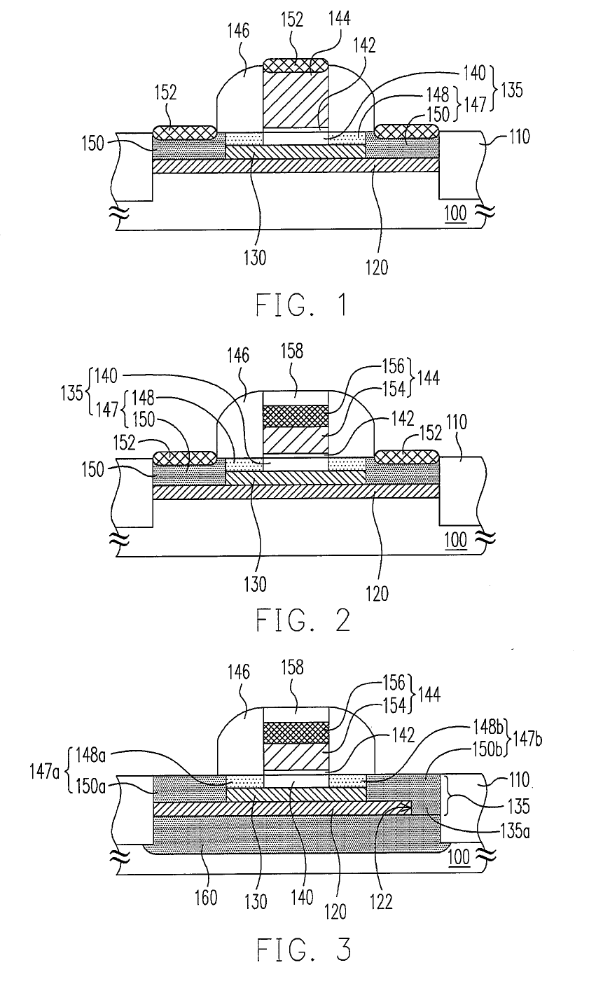

Referring to FIG. 3, the example of a fully depleted SOI device is similar to that shown in FIG. 1 or 2 except that a body contact 135a is disposed through the opening 122 of the first insulator 120 under a doped region (147b), wherein the body contact 135a is a portion of the semiconductor layer 135 filling in the opening 122. The doped region 147b can be electrically connected to the substrate 100, or alternatively to a well or a buried layer 160 in the substrate 100, via the body contact 135a. In addition, a salicide layer may be formed on the tops of the heavily doped portions 150a and 150b of the two doped regions 147a and 147b as an option.

### Second Embodiment

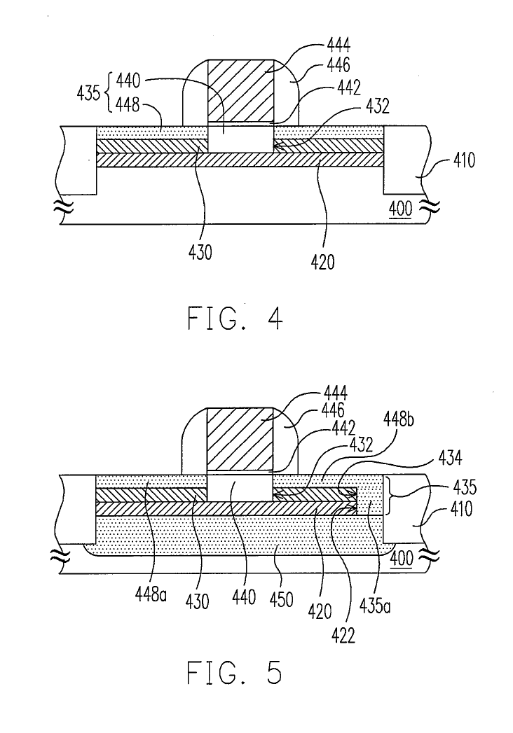

FIGS. 4-6 illustrate four examples of partially depleted SOI devices according to the second embodiment of this invention.

Referring to FIG. 4, the partially depleted SOI device includes a substrate 400, a first insulating layer 420 on the substrate 400, a second insulating layer 430 on the first insulating layer 420, a channel layer 440 on the first insulating layer 420, a gate dielectric layer 442 on the channel layer 440, a gate 444 on the gate dielectric layer 442, and two doped regions 448 as S/D regions beside the channel layer 440, wherein the channel layer 440 and the two doped regions 448 are defined from the same semiconductor layer 435 that forms the active area of the SOI device. The materials of the first and the second insulating layers 420 and 430 are different, as in the case of the first embodiment.

As shown in FIG. 4, the semiconductor layer 435 has a substantially planar surface and the second insulating layer 430 under the S/D regions 448 is reserved, but the portion of the second insulating layer 430 under the channel region 440 is etched off, so that the thickness of the channel layer 440 can be larger than 100 nm and the SOI device is a partially depleted MOS transistor during operation. Thus, the lower part of the channel layer 440 is embedded in an opening 432 in the second insulating layer 430.

In addition, the active area of the SOI device may be defined by an isolation structure 410, such as an STI structure. A conventional spacer 446 may be further formed on the sidewall of the gate 444 for forming LDD regions (not shown).

Referring to FIG. 5, the partially depleted SOI device is similar to that of FIG. 4 except that a body contact 435a is disposed through the opening 434 of the second insulating layer 430 and the opening 422 of the first insulating layer 420, both under a doped region (448b). The doped region 448b may be electrically connected to the substrate 400 or to a well or a buried layer 450 in the substrate 400.

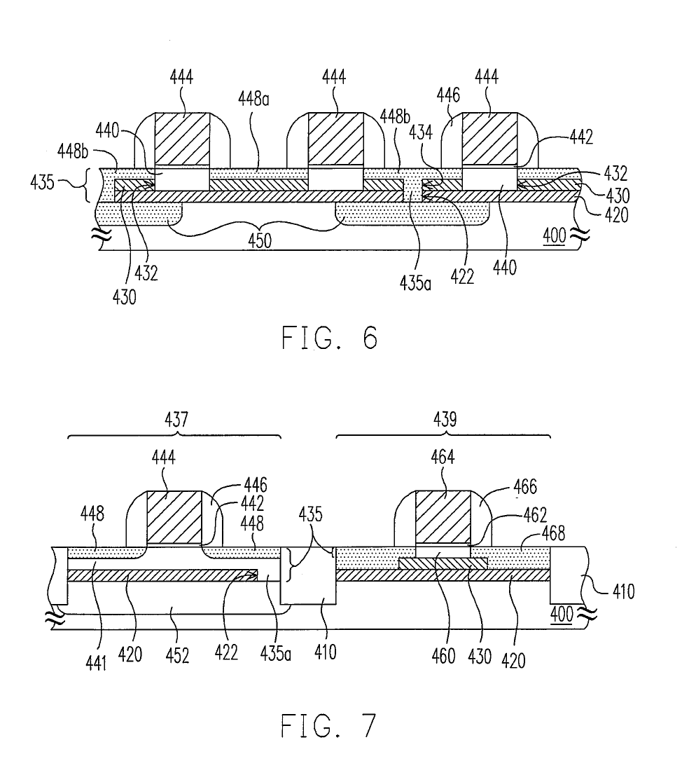

Referring to FIG. 6, the partially depleted SOI device is similar to that shown in FIG. 5 except that a body contact 435a is common for two adjacent MOS transistors. The doped region 448a of a MOS transistor, which is not connected to a body contact 435a, may also be shared by an adjacent MOS transistor.

### Third Embodiment

FIG. 7 illustrates an example of a semiconductor product that integrates an FD-SOI device and a partially depleted SOI device according to the third embodiment of this invention. Because the left half of the SOI device is similar to those mentioned in the second embodiment, similar reference numbers are used.

Referring to FIG. 7, the semiconductor layer 435 is formed for two kinds of MOS transistor, including a partially depleted one in the area 437 and a fully depleted one in the area 439. There is no second insulating layer 430 in the area 437 and the two doped regions 448 as S/D regions are formed shallow, so that the partially depleted MOS transistor in the area 437 contains a body layer 441.

Moreover, the first insulating layer 420 may have an opening 422 therein, possibly under a doped region 448, such that the body layer 441 is electrically connected to the substrate 400 or to a well or a buried layer 452 via the body contact 435a in the opening 422 to avoid floating body issue of conventional SOI devices.

Referring to FIG. 7 again, the MOS transistor in the area 437 can be replaced by any partially depleted transistor shown in FIG. 4 to FIG. 6 or the like, and the one in the area 439 can be any fully depleted transistor shown in FIG. 1 to FIG. 3 or the like. For example, the MOS transistor in the area 439 may be a fully depleted one that includes a channel layer 460 on the second insulating layer 430, a gate dielectric layer 462 and a gate 464 on the channel layer 460, and S/D regions 468 in the semiconductor layer 435 beside the gate 464. In addition, a spacer 466 can be disposed on the sidewall of the gate 464 for the same reasons mentioned above.

### Fourth Embodiment: Fabricating Process

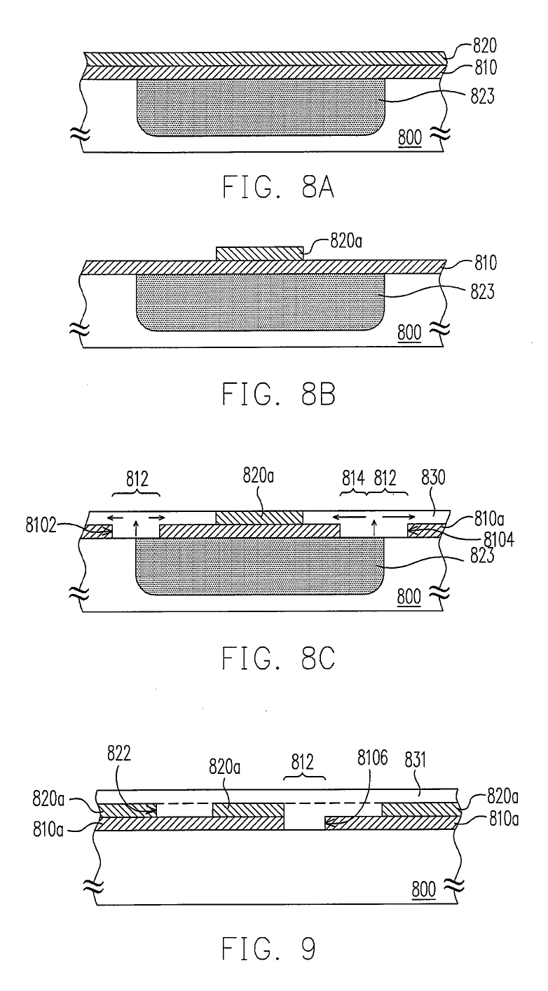

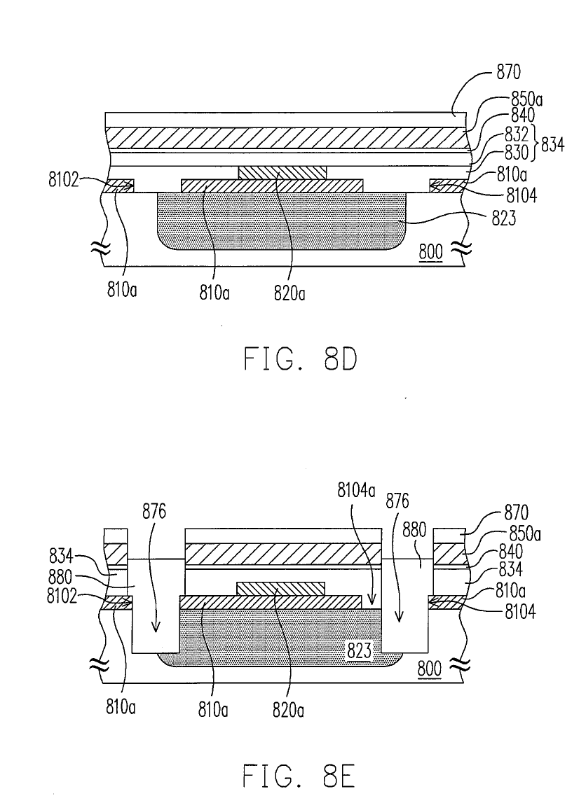

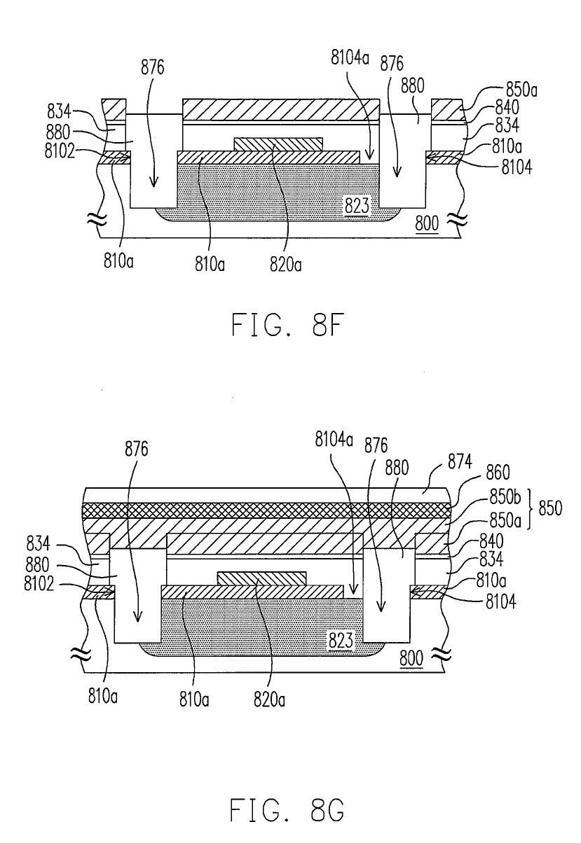

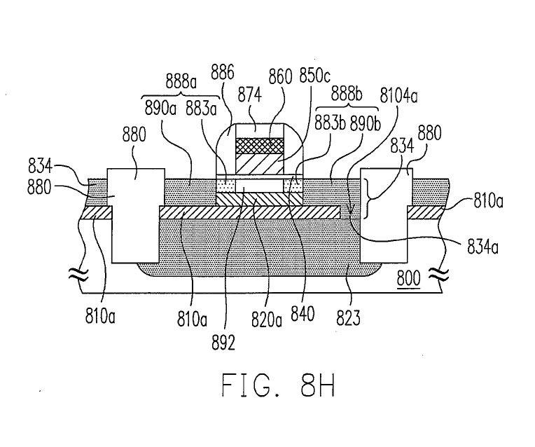

FIGS. 8A-8H illustrate, in a cross-sectional view, a process flow of fabricating an SOI device according to the fourth embodiment of this invention. Though the fourth embodiment is the fabricating process of the SOI device in FIG. 3, possible fabricating processes of other fully or partially depleted SOI devices with two insulating layers of this invention, such as those illustrated in FIGS. 1, 2 and 4-7, can be readily derived therefrom, because they are mainly different in the patterns of the first and the second insulating layers.

Referring to FIG. 8A, a first insulating layer 810 and a second insulating layer 820 are sequentially formed on a substrate 800 that may include a lightly doped crystalline semiconductor material like lightly P-doped single-crystal silicon. A well or a buried layer 823 may be formed in the substrate 800 before or after forming the insulating layers 810 and 820. The first insulating layer 810 and the second insulating layer 820 together constitute the insulator of the SOI structure, while their materials are preferably different. The first insulating layer 810 may include silicon oxide of about 2000 angstroms in thickness, and the second insulating layer 820 may include SiN of about 1000 angstroms in thickness. Each of the first and the second insulating layers 810 and 820 may be formed through chemical vapor deposition (CVD) like LPCVD or PECVD.

Referring to FIG. 8B, the second insulating layer 820 is patterned. The patterned second insulating layer 820a is for reducing the thickness of the channel layer (892, see FIG. 8H) to make the SOI device a fully depleted one, while the portions of the second insulating layer 820 in the areas corresponding to the heavily doped portions of the S/D regions are removed for increasing the thickness of the same to lower their resistance. Alternatively, to form a partially depleted SOI device as shown in FIG. 4, for example, the portion of the second insulating layer 820 in the area corresponding to the channel layer (892, FIG. 8H) is removed for forming a partially depleted SOI device. Meanwhile, the portions of the second insulating layer 820 in the areas corresponding to the heavily doped portions of S/D regions are reserved for forming shallow junctions.

Referring to FIG. 8C, after the second insulating layer 820 is patterned, the first insulating layer 810 may also be patterned for forming an opening of a body contact, or for exposing a portion of the substrate 800 for subsequent epitaxial growth and simultaneously facilitating the formation of isolation into the substrate 800, or for both purposes. When the first insulating layer 810 is patterned for both purposes, the portion thereof in the area 812 corresponding to the isolation structure subsequently formed and the portion in the area 814 corresponding to the body contact subsequently formed are both removed. Moreover, if the body contact is to be formed adjacent to the isolation structure, the opening in the first insulating layer 810a includes a narrower part 8102 corresponding to only the isolation structure and a wider part 8104 corresponding to the isolation structure and the substrate contact.

Thereafter, an epitaxial layer 830 is formed, filling all openings in the patterned first and second insulating layers 810a and 820a, wherein the top surface of the epitaxial layer 830 is coplanar with that of the second insulating layer 820a. The epitaxial layer 830 can be formed using any known method. In one method, selective epitaxy growth (SEG) is conducted from the exposed substrate 800 to fill the opening (8102+8104) in the first insulating layer 810a, as indicated by the vertical arrows. An epitaxial lateral overgrowth (ELO) process as described in U.S. Pat. No. 6,228,691 is then conducted to fill the opening in the second insulating layer 820a, as indicated by the horizontal arrows. The portion of the epitaxial layer 830 higher than the top surface of the second insulating layer 820a is then removed through, for example, chemical mechanical polishing (CMP), to expose the second insulating layer 820a.

Alternatively, a solid-state epitaxy method can be used to form the epitaxial layer 830. An amorphous silicon (a-Si) layer is formed, filling the openings in the first and second insulating layers 810a and 820a, and then a thermal annealing process is conducted, preferably at about 590° C. to 600° C., to grow silicon grains. Preferably, a high-temperature annealing step is further performed at 950° C. to 1100° C. in an ambient containing hydrogen gas after the thermal annealing process of 590° C. to 600° C. Then, the portion of the epitaxial layer higher than the top surface of the second insulating layer 820a is removed through CMP, for example. The CMP process is conducted until the second insulating layer 820a is exposed.

It is noted that when the second insulating layer 820a has an opening therein of which the bottom is entirely blocked by the first insulating layer 810a, as shown in FIG. 9, the opening 822 can also be filled with the above solid-state epitaxy method, or the above-mentioned SEG-ELO process, by which an epitaxial layer 831 is formed. The portion of the epitaxial layer 831 higher than the top surface of the second insulating layer 820a is removed later possibly through CMP, as indicated by the dashed lines.

Referring to FIG. 8D, another epitaxy layer 832 is formed on the epitaxial layer 830 and the second insulating layer 820a using, for example, the above solid-state epitaxy method. An a-Si layer is deposited to a thickness of 200 to 400 angstroms, and then the a-Si layer is annealed, preferably at about 590-600° C., to grow silicon grains. Similarly, a high-temperature annealing step may be performed at 950-1100° C. in an ambient containing hydrogen gas after the thermal annealing process of 590° C. to 600° C. The epitaxial layers 830 and 832 together constitute a semiconductor layer 834, which is namely the semiconductor part of an SOI substrate. After the semiconductor layer 834 is formed, a MOS transistor or any other type of semiconductor device can be fabricated based on it in any known MOS process.

For example, a MOS process where the gate dielectric layer is formed before the active area is defined can be applied, possibly in consideration of the quality of the gate dielectric layer. Such a MOS process is illustrated in FIGS. 8D-8H.

Referring to FIG. 8D again, a gate dielectric layer 840 and a poly-Si layer 850a are sequentially formed on the semiconductor layer 834. A hard mask layer 870 may be further formed on the poly-Si layer 850a, wherein the material of the hard mask layer 870 is usually SiN. The gate dielectric layer 840 may be a thin thermal oxide layer.

Referring to FIG. 8E, a lithography process and an etching process are conducted in sequence to form an isolation trench 876 through the hard mask layer 870, the polysilicon layer 850a, the gate dielectric layer 840, the semiconductor layer 834 and the first insulating layer 810a, and then into the substrate 800. Then, an insulating material like CVD-oxide is filled into the trench 876 to form an isolation structure 880.

When the etchant for the materials of the semiconductor layer 834 and the substrate 800 has a low etching selectivity to the material of the first insulating layer 810a, the trench 876 in the substrate 800 is partially defined by the opening (8102+8104) in the first insulating layer 810a. Since the narrower part 8102 of the opening corresponds to a portion of the isolation structure 880 only, as mentioned above, the entire narrower part 8102 is filled by the isolation structure 880. However, the wider part 8104 of the opening corresponds to a portion of the isolation structure 880 and the body contact, so that only a part of the wider part 8104 of the opening is occupied by the isolation structure 880 and an opening 8104a of the body contact is formed between the first insulating layer 810a and the isolation structure 880.

Referring to FIG. 8F, the hard mask layer 870 is removed through wet etching, for example. Referring to FIG. 8G, another polysilicon layer 850b is formed over the substrate 800 and then planarized, wherein the polysilicon layers 850a and 850b constitute a layer 850 for forming a gate electrode. A metal silicide layer 860, such as a tungsten silicide (WSi) layer, is formed on the polysilicon layer 850 to constitute a polycide structure. A cap layer 874 is preferably formed on the silicide layer 860.

Referring to FIG. 8H, the cap layer 874, the metal silicide layer 860 and the polysilicon layer 850 are patterned sequentially to form a gate including a polysilicon part 850c, and then ion implantation is conducted using the gate as a mask to form lightly doped portions 883a and 883b of the S/D regions 888a and 888b, thus defining a channel layer 892. A spacer 886 is then formed on the sidewall of the gate, and another implantation step is conducted using the gate and the spacer 886 as a mask to form the heavily doped portions 890a and 890b of the S/D regions 888a and 888b. The heavily doped portions 890a/b are formed down to the first insulating layer 810a.

In addition, to form a body contact 834a between the heavily doped portion 890b and the well or buried layer 823, the portion of the semiconductor layer 834 in the opening 8104a has to be doped. When the thickness of the first insulating layer 810a is sufficiently small, the dopant diffusion from the heavily doped portion 890b and the well or buried layer 823 in the thermal cycle is sufficient for doping the portion of the semiconductor layer 834. When the thickness of the first insulating layer 810a is larger such that the dopant diffusion effect is insufficient, however, the energy of the S/D implantation should be set higher to dope the portion of the semiconductor layer 834 in the opening 8104a.

Though the fourth embodiment is only a fabricating process of a single MOS transistor, it is easy to form a fully depleted MOS transistor and a partially depleted MOS transistor, two different fully depleted MOS transistors or two different partially depleted MOS transistors at the same time by forming different patterns of the first insulating layer and/or the second insulating layer in the areas of the two SOI devices. Accordingly, by modifying the above process within the scope of the present invention, it is also possible to form three or even more different SOI devices with two insulating layers on a substrate according to the present invention.

For example, a composite SOI device including a partially depleted MOS transistor in a first area and a fully depleted MOS transistor in a second area as illustrated in FIG. 7 can be made with a modified process of the above method. In the corresponding process, the portions of the second insulating layer 430 in the area 437 and the area of the isolation structure 410 are completely removed in the patterning step of the same, but the portion of the second insulating layer 430 corresponding to the channel layer 460 in the area 439 is not removed. Meanwhile, the S/D regions 448 are formed sufficiently shallow so that the body layer 441 can be connected to the substrate 400 or the well or buried layer 452, which is formed with the same conductivity type of the semiconductor layer 435 rather than that of the S/D regions 448.

In the above process of this invention, since the thickness of the second insulating layer 820 can be precisely controlled and the material of the second insulating layer 820 is different from that of the first insulating layer 810, the etching of the second insulating layer 820 can be easily controlled, and the thickness of the channel layer or the S/D regions can be precisely controlled to obtain more uniform electrical properties.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

What is claimed is:

1. A method for fabricating an SOI device, comprising:
forming a first insulating layer on a substrate;
forming a second insulating layer on the first insulating layer;
defining the second insulating layer;
forming a semiconductor layer, covering the first and the second insulating layers;
forming at least one semiconductor device based on the semiconductor layer.

2. The method of claim 1, wherein the semiconductor device comprises a MOS transistor and the step of forming the semiconductor device comprises:
forming a gate dielectric layer on the semiconductor layer;
forming a gate on the gate dielectric layer; and
forming two doped regions as source/drain regions in the semiconductor layer beside the gate.

3. The method of claim 2, wherein at least a portion of the second insulating layer in an area corresponding to the gate is not removed in the step of defining the second insulating layer.

4. The method of claim 3, wherein a portion of the second insulating layer in an area corresponding to a doped region is removed in the step of defining the second insulating layer.

5. The method of claim 2, wherein at least a portion of the second insulating layer in an area corresponding to the gate is removed in the step of defining the second insulating layer.

6. The method of claim 5, wherein a portion of the second insulating layer in an area corresponding to a doped region is not removed in the step of defining the second insulating layer.

7. The method of claim 1, wherein the substrate comprises silicon, and the first insulating layer comprises silicon oxide formed through thermal oxidation or CVD.

8. The method of claim 1, wherein the second insulating layer comprises silicon nitride formed through CVD.

9. The method of claim 1, wherein the substrate comprises silicon and the step of forming the semiconductor layer comprises:
forming an opening in the first insulating layer to expose a portion of the substrate;
depositing a first amorphous silicon layer, covering the first and the second insulating layers and filling the opening;
converting the first amorphous silicon layer to a first epitaxial layer based on the exposed substrate through thermal annealing;
planarizing the first epitaxial layer until the second insulating layer is exposed;
depositing a second amorphous silicon layer over the substrate; and
converting the second amorphous silicon layer to a second epitaxial layer through thermal annealing.

10. The method of claim 9, wherein the first and the second amorphous silicon layers are formed through CVD or PVD.

11. The method of claim 9, further comprising an in-situ cleaning step before the deposition of each of the first and the second amorphous silicon layers.

12. The method of claim 9, wherein the step of planarizing the first epitaxial layer comprises a chemical mechanical polishing (CMP) process.

13. The method of claim 9, wherein the thermal annealing is conducted at about 590° C. to 600° C.

14. The method of claim 13, further comprising a high-temperature annealing step at about 950° C. to 1100° C. in an ambient containing hydrogen gas after the thermal annealing at about 590° C. to 600° C.

15. The method of claim 1, wherein the substrate comprises silicon and the step of forming the semiconductor layer comprises:
forming an opening in the first insulating layer to expose a portion of the substrate;
conducting selective epitaxial silicon growth from the exposed substrate;
performing epitaxial lateral overgrowth to form a first epitaxial layer covering the first and the second insulating layers;
planarizing the first epitaxial layer until the second insulating layer is exposed;
depositing an amorphous silicon layer over the substrate; and
converting the amorphous silicon layer to a second epitaxial layer through thermal annealing.

16. The method of claim 1, wherein
two or more different semiconductor devices are formed based on the semiconductor layer; and
the second insulating layer is defined to have different patterns in active areas of the different semiconductor devices.

17. The method of claim 6, wherein
a first MOS transistor and a second MOS transistor are formed based on the semiconductor layer, wherein the first MOS transistor includes a first channel layer and the second MOS transistor includes a second channel layer;
a portion of the second insulating layer in an area corresponding to the first channel layer is not removed in the step of defining the second insulating layer; and
another portion of the second insulating layer in an area corresponding to the second channel layer is removed in the step of defining the second insulating layer.

18. A method for fabricating an SOI device, comprising:
forming an insulator on a substrate;
patterning but not etching through the insulator to form a cavity on the insulator;
patterning the insulator to form an opening exposing a portion of the substrate;
forming, based on epitaxial growth from the exposed substrate, a semiconductor layer covering the insulator, the opening and the cavity; and
forming a semiconductor device based on the semiconductor layer.

19. The method of claim 18, wherein the substrate comprises silicon and the step of forming the semiconductor layer comprises:
depositing a first amorphous silicon layer over the substrate;
converting the first amorphous silicon layer to a first epitaxial layer based on the exposed substrate through thermal annealing;
planarizing the first epitaxial layer until the insulator is exposed;
depositing a second amorphous silicon layer over the substrate; and
converting the second amorphous silicon layer to a second epitaxial layer through thermal annealing.

20. The method of claim 19, wherein the first and the second amorphous silicon layers are deposited through CVD or PVD.

21. The method of claim 19, further comprising an in-situ cleaning step before the deposition of each of the first and the second amorphous silicon layers.

22. The method of claim 19, wherein the step of planarizing the first epitaxial layer comprises a CMP process.

23. The method of claim 19, wherein the thermal annealing is conducted at 590° C. to 600° C.

24. The method of claim 23, further comprising a high-temperature annealing step at about 950° C. to 1100° C. in an ambient containing hydrogen gas after the thermal annealing at 590° C. to 600° C.

25. The method of claim 18, wherein the substrate comprises silicon and the step of forming the semiconductor layer comprises:
conducting selective epitaxial silicon growth from the exposed substrate;
performing epitaxial lateral overgrowth to form a first epitaxial layer;
planarizing the first epitaxial layer until the insulator is exposed;
depositing an amorphous silicon layer over the substrate;
converting the amorphous silicon layer to a second epitaxial layer through thermal annealing.

26. The method of claim 25, wherein the thermal annealing is conducted at 590° C. to 600° C.
